(19) United States
(12) Patent Application Publication
(10) Pub. No.: US 2026/0367295 A1
(43) Pub. Date: Nov. 19, 2026

(54) SURFACE RELIEF GRATING APPARATUS AND MANUFACTURING METHOD

(71) Applicant: Dispelix Oy, Espoo (FI)

(72) Inventor: Ismo Vartiainen, Espoo (FI)

(21) Appl. No.: 19/206,133

(22) Filed: May 13, 2025

(51) Int. Cl. G02B 5/18; G02B 1/11

(52) U.S. Cl. CPC G02B 5/1842; G02B 1/11; G02B 5/1847

(57) ABSTRACT

A method of manufacturing a surface relief grating (300), comprising bonding a transfer film (32), comprising a functional layer such as an anti-reflection layer (305) attached to a carrier (312), onto a grating surface profile (31), and removing a sacrificial portion of the transfer film (32). An apparatus for a waveguide combiner of a see-through display device comprises a grating surface profile (31) of a surface relief grating, and a functional layer (305) as a transfer film layer on the grating surface profile (31).

### FIELD

The present disclosure generally relates to see-through display devices.

### BACKGROUND

This section illustrates useful background information without admission of any technique described herein representative of the state of the art.

In see-through display devices, such as in devices for extended reality (XR) applications, transparent waveguide combiners may be used as see-through displays to optically combine real and virtual worlds in a user's field of vision.

In such devices light from a light engine typically enters the waveguide combiner via a light in-coupling section, propagates within the waveguide combiner by total internal reflection, and exits the waveguide combiner via a light out-coupling section, the waveguide combiner typically also comprising an exit pupil expander (EPE) conveniently expanding the output light for a pupil of an eye of a user.

Surface relief gratings are commonly used in the light in-coupling and out-coupling sections. Such gratings typically contain grooves in between grating ridges, wherein advantageous grating responses may be obtained by applying ridges of high refractive index material. However, applying high refractive index material may result in unwanted features, such as high specular reflection. Gratings may appear visible due to reflected light. An effect known as the rear-view mirror effect may be caused.

### SUMMARY

It is an object of certain embodiments of the present disclosure to reduce reflection in surface relief gratings or respective apparatuses or at least to provide an alternative solution to existing technology.

According to a first example aspect of the present disclosure there is provided a method of manufacturing a surface relief grating, comprising:
bonding a transfer film, comprising a functional layer attached to a carrier, onto a grating surface profile; and
removing a sacrificial portion of the transfer film.

In certain embodiments, the functional layer is an anti-reflection layer. In certain embodiments, the functional layer comprises at least one of the following: an anti-reflection layer, a dielectric stack, a second grating (there being a planar layer in between said grating surface profile and the second grating), a notch filter, a dichroic mirror.

In certain embodiments, air is trapped inside the grating during said bonding a transfer film onto the grating surface profile.

Accordingly, in certain embodiments, the surface relief grating is an air-filled grating. In certain embodiments, the surface relief grating comprises air pockets formed between the grating surface profile and the functional layer. In certain embodiments, the grating surface profile comprises ridges separated by grooves. In certain embodiments, the (air-filled) surface relief grating comprises air within said grooves. In certain embodiments, by the grating surface profile is meant a surface structure of the grating.

In certain embodiments, the method comprises:
transferring the transfer film as a whole onto the grating surface profile.

Accordingly, in certain embodiments, the transfer film is a ready-made film.

In certain embodiments, the transfer film comprises the functional layer provided with an adhesive.

In certain embodiments, the transfer film comprises a bonding layer, such as an adhesive layer, underneath the functional layer.

In certain embodiments, the method comprises:
forming an encapsulated structure by attaching the transfer film onto the grating surface profile.

In certain embodiments, the carrier comprises a carrier film.

In certain embodiments, said removing a sacrificial portion of the transfer film comprises removing a carrier film.

In certain embodiments, said removing a sacrificial portion of the transfer film further comprises removing a release layer.

In certain embodiments, the transfer film comprises the functional layer attached to the carrier film on top through the release layer.

In certain embodiments, the transfer film comprises a materials stack comprising a release layer in between a carrier film and the functional layer. In certain embodiments, the transfer film comprises a materials stack comprising a release layer in between a carrier film and the functional layer, and an adhesive layer (bonding layer) beneath the functional layer. In certain embodiments, the adhesive layer (bonding layer) is in direct contact with the functional layer. In certain embodiments, the adhesive layer (bonding layer) is in direct contact both with the functional layer and with the grating surface structure. In certain embodiments, the adhesive layer (bonding layer) is a material layer of one substance.

In certain embodiments, the grating surface profile is of material whose refraction index is 1.7 or higher, preferably 2.0 or higher.

In certain embodiments, the grating surface profile is of TiO₂, and the functional layer is of SiO₂.

In certain embodiments, the method comprises manufacturing a surface relief grating of a waveguide combiner and/or a surface relief grating of a see-through display device.

In certain embodiments, the method comprises manufacturing an in-coupling grating, an out-coupling grating, or an exit pupil expander grating.

Advantageously, the surface relief grating is manufactured without filling the grating (or gaps of the grating) with solid material.

According to a second example aspect of the present disclosure there is provided an apparatus, comprising:
a grating surface profile of a surface relief grating; and
a functional layer as a transfer film layer on the grating surface profile.

In certain embodiments, the functional layer is an anti-reflection layer. In certain embodiments, the functional layer comprises at least one of the following: an anti-reflection layer, a dielectric stack, a second grating (there being a planar layer in between said grating surface profile and the second grating), a notch filter, a dichroic mirror.

In certain embodiments, the apparatus comprises the functional layer and an adhesive transferred onto the grating surface profile.

In certain embodiments, the apparatus comprises air in gaps in between the grating surface profile and the functional layer.

Accordingly, in certain embodiments, the apparatus is or comprises an air-filled surface relief grating.

In certain embodiments, the apparatus is a surface relief grating or an apparatus comprising a surface relief grating, such as a waveguide combiner of a see-through display device.

Different non-binding example aspects and embodiments have been illustrated in the foregoing. The above embodiments are used merely to explain selected aspects or steps that may be utilized in implementations of the present disclosure. Some embodiments may be presented only with reference to certain example aspects. It should be appreciated that corresponding embodiments apply to other example aspects as well. In particular, the embodiments described in the context of the first aspect are applicable to each further aspect, and vice versa. Any appropriate combinations of the embodiments may be formed.

### BRIEF DESCRIPTION OF THE DRAWINGS

The present disclosure will now be described, by way of example only, with reference to the accompanying drawings, in which:

FIG. 1 shows an example of a see-through display device in accordance with certain embodiments;

FIG. 2 shows a waveguide combiner in accordance with certain embodiments;

FIG. 3 shows a schematic cross-sectional view of an apparatus in accordance with certain embodiments;

FIGS. 4a-4d show manufacturing steps for manufacturing an apparatus in accordance with certain embodiments; and

FIG. 5 shows a flow chart in accordance with certain embodiments.

### DETAILED DESCRIPTION

In the following description, like reference signs denote like elements or steps.

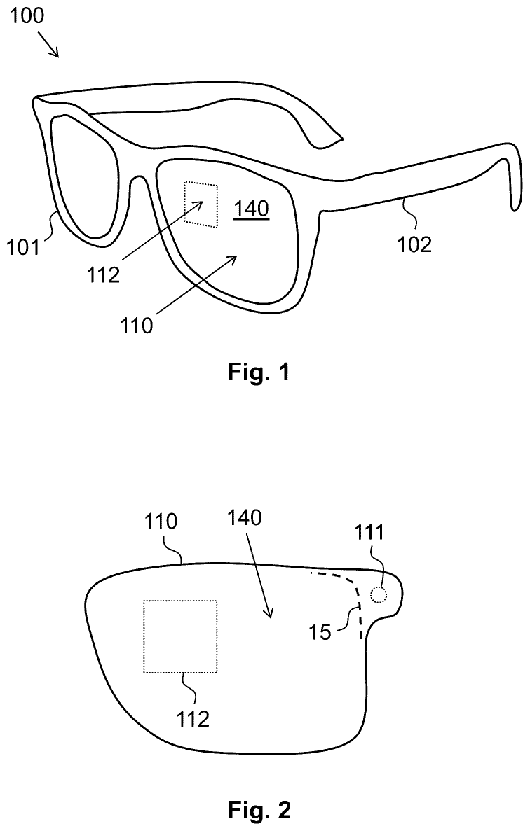

FIG. 1 shows an example of a see-through display device 100 in accordance with certain embodiments. The see-through display device 100 comprises a waveguide combiner 110 to optically combine real and virtual worlds in a user's field of vision. The see through display device 100 may be a near-to-eye display device, such as extended reality (XR) glasses. The waveguide combiner 110 comprises an optical waveguide 140. Light trapped into the optical waveguide 140 exits from the optical waveguide 140 via an out-coupling section 112. In certain embodiments, the optical waveguide 140 is of transparent material (to visible light). In certain embodiments, the optical waveguide 140 is a single layer waveguide. In certain embodiments, the optical waveguide 140 is an essentially planar or two-dimensional waveguide. The term planar or two-dimensional is used herein to distinguish from optical fibers or other tubular waveguides. Therefore, the essentially planar or two-dimensional waveguide herein may be curved such as a lens of glasses (prescription lens) or a visor of a helmet or similar.

The see-through display device 100 further comprises a light engine (not shown) attached to the waveguide combiner 110. In the example of XR glasses or the like, the light engine may be embedded into a temple 102 of the glasses and covered by a frame 101 of the glasses. In certain embodiments, the see-through display device 100 comprises a respective waveguide combiner 110 for both eyes of a user.

FIG. 2 shows an example of the waveguide combiner 110 for one eye. The optical waveguide 140 of the waveguide combiner 110 receives light from the light engine (not shown) via a light in-coupling section 111. The light propagates within the optical waveguide 140 by total internal reflection and exits the optical waveguide 140 via the light out-coupling section 112 that preferably also comprises an exit pupil expander (EPE, not shown) conveniently expanding output light for a pupil of the eye of the user. In certain embodiments, the light in-coupling section 111 comprises an in-coupling grating (not shown in FIGS. 1 and 2). In certain embodiments, the light out-coupling section 112 comprises an out-coupling grating (not shown in FIGS. 1 and 2). In certain embodiments, the exit pupil expander is implemented by a third grating. In certain embodiments, the out-coupling grating and the exit pupil expander are combined into a single grating structure. The reference numeral 15 shows a frame cover borderline. As will be noted, the light in-coupling section 111 and the respective light engine in certain embodiments is covered by the frame (101, FIG. 1) of see-through display device 100.

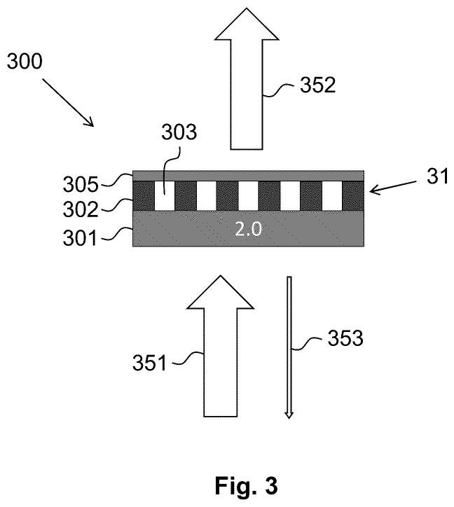

FIG. 3 shows a schematic cross-sectional view of an apparatus in accordance with certain embodiments. In particular, FIG. 3 shows a surface relief grating 300 which can be embodied in see-through display devices or similar. Applicable uses of such gratings are various in-coupling gratings, out-coupling gratings and exit pupil expander gratings of waveguide combiners or the like.

It has been observed that advantageous grating responses may be obtained with the disclosed structure comprising high refractive index material. The structure comprises a substrate 301 manufactured of high refractive index material. Herein, by high refractive index material is meant material whose refraction index is 1.7 or higher, preferably 2.0 or higher, but the definition of high refractive index material depends on the embodiment. In certain embodiments, the substrate 301 acts as a waveguide layer. A grating surface profile 31 comprising grooves 303 in between ridges 302 is located on the substrate 301. A functional layer 305 covers the grating surface profile 31. In a specific embodiment, a function of the functional layer 305 is to reduce reflection. Accordingly, the functional layer 305 in certain embodiments may be an anti-reflection layer. In certain embodiments, the grating 300 comprises air within said grooves 303.

In some embodiments, the structure comprises one or more additional material layers between the substrate 301 and the grating surface profile 31 (not shown). The one or more additional material layers may be implemented e.g. for reasons to improve optical properties in certain embodiments. In certain embodiments, the one or more additional material layers reside on the substrate, and the grating surface profile on the one or more additional material layers.

In certain embodiments, the ridges 302 are of high refractive index material (preferably different high refractive index material than the substrate 301). In certain embodiment, the functional layer 305 is of lower refractive index material. In certain embodiments, the grating surface profile 31 is of TiO₂, and the functional layer 305 is of SiO₂. In some embodiments, the ridges of the grating surface profile comprise at least two material layers of different material.

In a realistic embodiment, a 1-2% specular reflection 353 for a normal incidence 351 may be achieved by the shown grating structure, wherein transmission is denoted by reference numeral 352 in the drawing. Without the layer 305, the same grating structure has approximately 10% reflection at normal incidence for visible light spectrum.

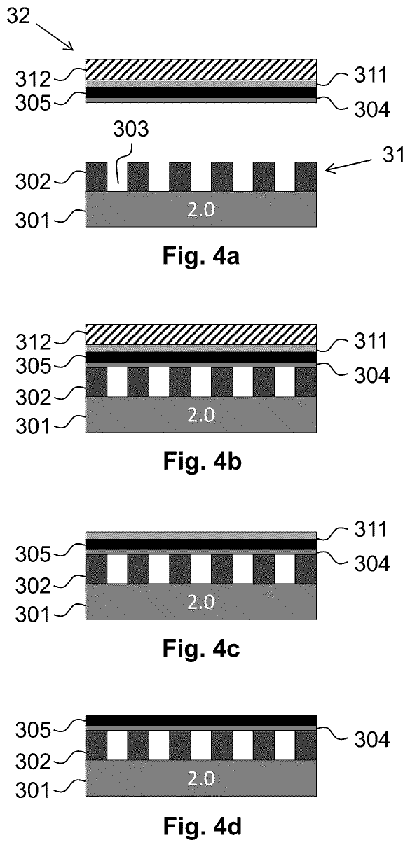

FIGS. 4a-4d show manufacturing steps for manufacturing the type of grating 300 shown in FIG. 3 in accordance with certain embodiments. The manufacturing steps comprise bonding a transfer film 32, comprising a functional layer 305, attached to a carrier, onto a grating surface profile 31, and removing a sacrificial portion of the transfer film 32.

In more detail, as an initial step there is provided the substrate 301 having the grating surface profile 31 thereon. Further, there is provided the transfer film 32 comprising the functional layer 305. In certain embodiments, the transfer film 32 comprises a layered materials stack comprising the following layers from bottom to top: an adhesive layer 304, the functional layer 305, preferably of SiO₂, a release layer 311, and a carrier film 312. FIG. 4a shows this initial step.

Subsequently, as set out in FIG. 4b, the transfer film 32 is transferred onto the grating surface profile 31 (or ridges 302). The adhesive layer 304 adheres to the ridges 302 to achieve a proper bonding. Air is trapped inside the grating (or grooves 303) during the bonding to obtain a high contrast between the refractive indices of the ridges 302 and grooves 303.

In certain embodiments, the refractive index of the adhesive layer 304 is matched with the refractive index of the functional layer 305 so that there is no optical interface formed between the adhesive layer 304 and the functional layer 305. In other embodiments, the refractive index of the adhesive layer 304 is different from the refractive index of the functional layer 305. In certain embodiments, the refractive index of the adhesive layer 304 is different from the refractive index of the material of the grating (ridges 302).

Subsequently, as set out in FIG. 4c, the carrier film 312 is removed.

Subsequently, as set out in FIG. 4d, the release layer 312 is removed.

Any conventional layer removal mechanisms may be used.

As a result, an air-filled high refractive index grating with desired functional properties, such as anti-reflection properties, is obtained. In certain embodiments, the functional layer 305 comprises at least one of the following: an anti-reflection layer, a dielectric stack, a second grating, a notch filter, a dichroic mirror. In the event of the second grating, in certain embodiments, there is provided a planar layer in between said grating surface profile 31 (of the “first” grating) and the second (additional) grating.

In the embodiments of FIGS. 3 and 4a-4d a binary grating is shown. In other embodiments, the grating may be of the type other than a binary grating. In some embodiments, the grating may be, e.g., a slanted grating or a blazed grating.

Further, although the embodiments of FIGS. 3 and 4a-4d show a simple 1-dimensional grating, in other embodiments the grating may be a 2-dimensional grating. Such a 2-dimensional may be formed by repeating a 2-dimensional grating unit cell in two directions. In such embodiments the transfer film is transferred respectively onto the grating surface profile of the 2-dimensional grating. The 2-dimensional grating may have, e.g., a shape of a rectangular lattice, a hexagonal lattice, a rhombic lattice, or a diamond lattice.

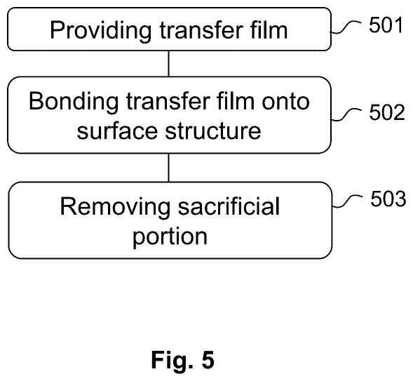

FIG. 5 shows a flow chart in accordance with certain embodiments of the present disclosure. In more detail, certain general features of the above-presented manufacturing method are shown. In step 501, a transfer film comprising a functional layer or coating, such as an anti-reflection coating, is provided. Subsequently, in step 502, the transfer film is bonded onto a grating surface structure. Finally, a sacrificial portion of the transfer film is removed, in step 503, to obtain a finished grating.

Without limiting the scope and interpretation of the patent claims, certain technical effects of one or more of the example embodiments disclosed herein are listed in the following. A technical effect is providing a manufacturing method for a grating having advantageous grating responses and a functional feature, such as an anti-reflection feature (also reducing a rear-view mirror effect). A technical effect is a surface relief grating that is less visible to a user. Another technical effect is at least a partial simplification of a grating manufacturing method. Another technical effect is an easier or cheaper manufacturing method. Another technical effect is planarization of the grating surface due to the usage of the transfer film.

The foregoing description has provided by way of non-limiting examples of particular implementations and embodiments of the invention a full and informative description of the best mode presently contemplated by the inventors for carrying out the invention. It is however clear to a person skilled in the art that the invention is not restricted to details of the embodiments presented above, but that it can be implemented in other embodiments using equivalent means without deviating from the characteristics of the invention.

Furthermore, some of the features of the above-disclosed embodiments of this invention may be used to advantage without the corresponding use of other features. As such, the foregoing description should be considered as merely illustrative of the principles of the present invention, and not in limitation thereof. Hence, the scope of the invention is only restricted by the appended patent claims.

1. A method of manufacturing a surface relief grating, comprising:
bonding a transfer film, comprising a functional layer attached to a carrier, onto a grating surface profile; and
removing a sacrificial portion of the transfer film.

2. The method of claim 1, wherein the functional layer is an anti-reflective layer.

3. The method of claim 1, wherein air is trapped inside the grating during said bonding a transfer film onto the grating surface profile.

4. The method of claim 1, comprising:
transferring the transfer film as a whole onto the grating surface profile.

5. The method of claim 1, wherein the transfer film comprises the functional layer provided with an adhesive.

6. The method of claim 1, comprising:
forming an encapsulated structure by attaching the transfer film onto the grating surface profile.

7. The method of claim 1, any wherein said removing a sacrificial portion of the transfer film comprises removing a carrier film.

8. The method of claim 7, wherein said removing a sacrificial portion of the transfer film further comprises removing a release layer.

9. The method of claim 1, wherein the grating surface profile is of a material whose refraction index is 1.7 or higher, preferably 2.0 or higher.

10. The method of claim 1, wherein the grating surface profile is of TiO₂, and the functional layer is of SiO₂.

11. The method of claim 1, wherein the method comprises manufacturing a surface relief grating of a waveguide combiner and/or a surface relief grating of a see-through display device.

12. An apparatus, comprising:
a grating surface profile of a surface relief grating; and
a functional layer as a transfer film layer on the grating surface profile.

13. The apparatus of claim 12, wherein the functional layer is an anti-reflective layer.

14. The apparatus of claim 12, comprising the functional layer and an adhesive transferred onto the grating surface profile.

15. The apparatus of claim 12, comprising air in gaps in between the grating surface profile and the functional layer.

16. The apparatus of claim 12, wherein the apparatus is a surface relief grating or an apparatus comprising a surface relief grating, such as a waveguide combiner of a see-through display device.
